(19) United States
(12) Patent Application Publication
(10) Pub. No.: US 2006/0145356 A1
(43) Pub. Date: Jul. 6, 2006

(54) ON-CHIP COOLING

(75) Inventors: Hsichang Liu, Fishkill, NY (US); Louis Lu-Chen Hsu, Fishkill, NY (US); William Robert Tonti, Essex Junction, VT (US)

Correspondence Address: FREDERICK W. GIBB, III;GIBB INTELLECTUAL PROPERTY LAW FIRM, LLC, 2568-A RIVA ROAD, SUITE 304, ANNAPOLIS, MD, 21401, US

(73) Assignee: INTERNATIONAL BUSINESS MACHINES CORPORATION, Armonk, NY (US)

(21) Appl. No.: 10/905,478

(22) Filed: Jan. 6, 2005

(51) Int. Cl. H01L 23/52

(52) U.S. Cl. 257/777

(57) ABSTRACT

A method and structure for forming an integrated circuit chip that forms thermal conductors in a second wafer, and bonds the second wafer to a first wafer. Then circuits are formed in the first wafer. The thermal conductors in the second wafer have a higher coefficient of thermal conductivity than the second wafer and the bonding process seals the thermal conductors within the second wafer. Chip carrier connections are formed on the side of the first wafer that is opposite to the side where the first wafer is bonded to the second wafer, and then the first wafer can be bonded to a chip carrier. The second wafer has a coefficient of thermal expansion that matches a coefficient of thermal expansion of the first wafer.

### BACKGROUND OF THE INVENTION

1. Field of the Invention

The invention generally relates to a method of forming an integrated circuit chip that forms circuits in a first wafer, forms thermal conductors in a second wafer, and bonds the second wafer to the first wafer.

2. Description of the Related Art

Conventional semiconductor cooling system via passive or active means is mostly implemented at the module level. However, as feature sizes are progressively shrunk, circuit densities are increased, even though power supply is down-scaled, and the power density consumed by the chip continues to increase from generation to generation. As the result of this trend, more sophisticated and expensive cooling systems are required to accommodate the increasing heat dissipation rate. Package thermal management has become one of the most challenging fields in today's IC design.

It is conceivable that cooling devices will be included closer and closer to the chip. On the other hand, wafer thickness increases as wafer size is grown. As the wafer diameter is increased, more chips can be yielded, and thus cost per chip can be reduced. As wafer size is grown, in order to provide sufficient mechanical strength, wafer thickness must be proportionally increased. Therefore, heat dissipated from the back side of the wafer becomes more difficult. This problem is aggravated when using silicon on insulator (or SOI) wafer, since thermal resistance through the buried oxide layer is worse than the silicon. The invention discussed below addresses these concerns.

### SUMMARY OF THE INVENTION

Disclosed herein is a method of forming an integrated circuit chip that forms thermal conductors in a second wafer, and bonds the second wafer to a first wafer. Then circuits are formed in the first wafer. The thermal conductors in the second wafer have a higher coefficient of thermal conductivity than the second wafer and the bonding process seals the thermal conductors within the second wafer. Chip carrier connections are formed on the side of the first wafer that is opposite to the side where the first wafer is bonded to the second wafer, and then the first wafer can be bonded to a chip carrier. The second wafer has a coefficient of thermal expansion that matches a coefficient of thermal expansion of the first wafer.

The process of forming the thermal conductors can form thermoelectric devices within the second wafer. Alternatively, the thermal conductors can be formed by etching trenches in the wafer and then filling the trenches with material having a higher coefficient of thermal conductivity than the second wafer.

Thus, the invention produces a laminated chip structure that has a thermally conductive surface connected to the portion of the chip that contains the actual circuits. In another embodiment, the invention can connect multiple chips to a flexible substrate and fold the flexible substrate. More specifically, the invention connects a first integrated circuit chip and a second integrated circuit chip to the flexible substrate. For example, the first and second integrated circuit chips can each comprise a first portion comprising circuits and a second portion comprising trenches filled with thermal conductors.

A thermally conductive surface (e.g., a thermal plate) is joined to the top (second portion) of the first chip. This embodiment then folds the flexible substrate such that the top (second portion) of the second integrated circuit chip contacts the thermal plate. This process of folding the flexible substrate inverts the second integrated circuit chip with respect to the first integrated circuit chip and positions the thermal plate between the tops of the two chips. The first integrated circuit chip and the second integrated circuit chip are positioned such that the thermal conductors are between the thermally conductive surface and the circuits. Then, the second integrated circuit chip is bonded to the thermal plate.

Another embodiment of the invention bonds a first wafer to a sacrificial wafer, forms circuits in the first wafer, dices the wafer into integrated circuit chips, attaches the first wafer to a chip carrier, disconnects the sacrificial wafer from the first wafer, and optionally bonds the heat sink to the first wafer. The process of bonding the first wafer to the sacrificial wafer forms a non-permanent bond that is broken during the process of disconnecting the sacrificial wafer from the first wafer. The heat sink is an air-cooled structure with cooling fins.

These, and other, aspects and objects of the present invention will be better appreciated and understood when considered in conjunction with the following description and the accompanying drawings. It should be understood, however, that the following description, while indicating preferred embodiments of the present invention and numerous specific details thereof, is given by way of illustration and not of limitation. Many changes and modifications may be made within the scope of the present invention without departing from the spirit thereof, and the invention includes all such modifications.

### BRIEF DESCRIPTION OF THE DRAWINGS

The invention will be better understood from the following detailed description with reference to the drawings, in which:

FIG. 1 is a schematic cross-sectional view diagram of a first embodiment according to the invention;

FIG. 2 is a schematic cross-sectional view diagram of a first embodiment according to the invention;

FIG. 3 is a schematic cross-sectional view diagram of a first embodiment according to the invention;

FIG. 4 is a schematic cross-sectional view diagram of a first embodiment according to the invention;

FIG. 5 is a schematic perspective view diagram of a first embodiment according to the invention;

FIG. 6 is a schematic cross-sectional view diagram of a first embodiment according to the invention;

FIG. 7 is a schematic cross-sectional view diagram of a first embodiment according to the invention;

FIG. 8 is a schematic cross-sectional view diagram of a first embodiment according to the invention;

FIG. 9 is a schematic cross-sectional view diagram of a first embodiment according to the invention;

FIG. 10 is a schematic cross-sectional view diagram of a first embodiment according to the invention;

FIG. 11 is a schematic cross-sectional view diagram of a second embodiment according to the invention;

FIG. 12 is a schematic cross-sectional view diagram of a second embodiment according to the invention;

FIG. 13 is a schematic cross-sectional view diagram of a second embodiment according to the invention;

FIG. 14 is a schematic cross-sectional view diagram of a second embodiment according to the invention;

FIG. 15 is a schematic cross-sectional view diagram of a second embodiment according to the invention;

FIG. 16 is a schematic cross-sectional view diagram of a second embodiment according to the invention;

FIG. 17 is a schematic cross-sectional view diagram of a second embodiment according to the invention;

FIG. 18 is a schematic cross-sectional view diagram of a second embodiment according to the invention;

FIG. 19 is a flow diagram illustrating a first method of the invention; and

FIG. 20 is a flow diagram illustrating a second method of the invention.

### DETAILED DESCRIPTION OF PREFERRED EMBODIMENTS OF THE INVENTION

As mentioned above, there is a need to increase the efficiency of cooling in today's integrated circuit chips. One method for doing so is to include cooling structures within the circuitry of the chip or attach cooling structures to the chips. However, these solutions reduce chip packing density. Extra chip area must be allocated to form internal thermal cooling trenches or cooling channels, which displaces the active circuitry. Similarly, devices attached to the exterior of a chip increase the overall size, weight, and expense. In the IC chips, higher circuit density areas always produce more thermal flux. Therefore, higher circuit densities require more efficient thermal dissipation. Installing thermal path devices side-by-side with high-density circuits means less actual devices can be integrated per unit area, which eventually leads to larger chip size.

Further, if cooling trenches are used, such trenches must be smaller and deeper than trenches formed for other uses. Due to area constrains, the trench size must be relatively small. In order to extend the trench across the full chip thickness, very high-aspect ratio trenches are needed. Forming these trenches is not an easy task, and is also a time consuming and expensive process.

Another problem with using internal cooling systems is that, since cooling trenches will be positioned side-by-side and relatively close to the real devices, the reliability of the devices will be degraded due to the presence of stress induced dislocations and defects. Similarly, metal interconnects would be affected by the placement of internal cooling trenches. If internal cooling trenches were used, interconnect quality would be compromised. For example, the metal width as well as routing of the wires would have to consider the location of the cooling trenches. In fact, metal itself is a good thermal conductor, and adding thermal paths through metal layers is redundant and thus unnecessary. Therefore, the invention presents a method that forms a separate wafer that is used exclusively for the internal cooling trenches, and bonds this wafer with the cooling device to the wafer in which the integrated circuit structures (active devices and/or circuits) are formed. Therefore, the invention essentially segregates the chip into two distinct portions, one of which includes the circuits and one of which includes cooling devices. By previously forming the cooling devices in a separate wafer and then bonding this “cooling wafer” to the wafer in which the active circuits performed, the invention avoids the forgoing problems that occur when the cooling devices are integrated within the same area in which the active circuitry is formed.

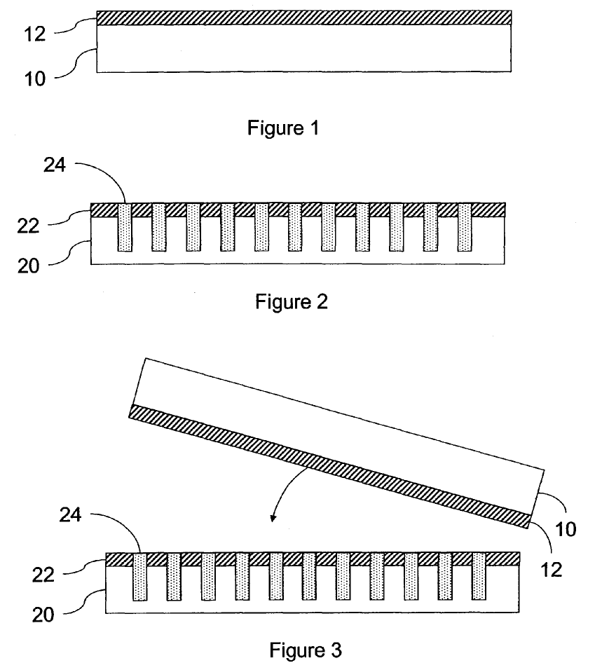

More specifically, as shown in FIG. 1, the invention begins with a conventional wafer 10 (which is sometimes referred to herein as the “first” wafer). The first wafer 10 is the wafer in which the active circuits will be formed. The wafers mentioned herein can comprise any form of wafer such as silicon based wafers, or any other type of similar wafers. A cap dielectric layer 12 is formed over the first wafer 10. This dielectric layer can comprise any form of insulator, such as silicon dioxide, and can be formed using any conventional insulator formation process such as a thermal oxidation, or deposition. It can also be a thermally conductive CVD (chemical vapor deposition) diamond.

FIG. 2 illustrates the cooling wafer that will be attached to the first wafer 10. The cooling wafer 20 is sometimes referred to herein as the second wafer 20. In a similar manner to the first wafer 10, a cap dielectric layer 22 is formed over the second wafer 20. While cap dielectric layers 12, 22 are shown as being formed on both the first wafer 10 and the second wafer 20, since the wafers 10, 20 will be bonded together as shown in FIG. 3, embodiments herein may, in certain circumstances, utilize only one cap dielectric layer on either the first wafer 10 or the second wafer 20.

Thermal conductors 24 are formed within the second wafer 20. These thermal conductors 24 are formed of a material that has a very high coefficient of thermal conductivity. Therefore, the thermal conductors 24 will have a higher coefficient of thermal conductivity than the wafer material 10, 20. The thermal conductors 24 can comprise any type of material or structure that is efficient at transferring heat away from the active region of the chip. For example, the thermal conductors 24 can comprise trenches filled with metals, polymers, CVD diamond, and other similar materials. Alternatively, the thermal conductors 24 can comprise cooling channels through which a cooling fluid can be transported. This may be in the form of a “removable” assembly, used specifically for burn-in, where active cooling is required. Also, the thermal conductors 24 can comprise thermal electric devices that actively absorb heat from one region and transfer the heat to another region. In addition, the thermal conductors 24 can comprise any other type of device or structure that is useful for transferring heat whether currently known or developed in the future. One point aspect of the invention is the use of thermal conductors in a separate substrate from the substrate in which circuits will be formed, and this is independent of the type of thermal conductor utilized. The methods and materials used to form such thermal conductors are well known to those ordinarily skilled in the art and are not discussed in detail herein so as not to obscure the salient features of the invention.

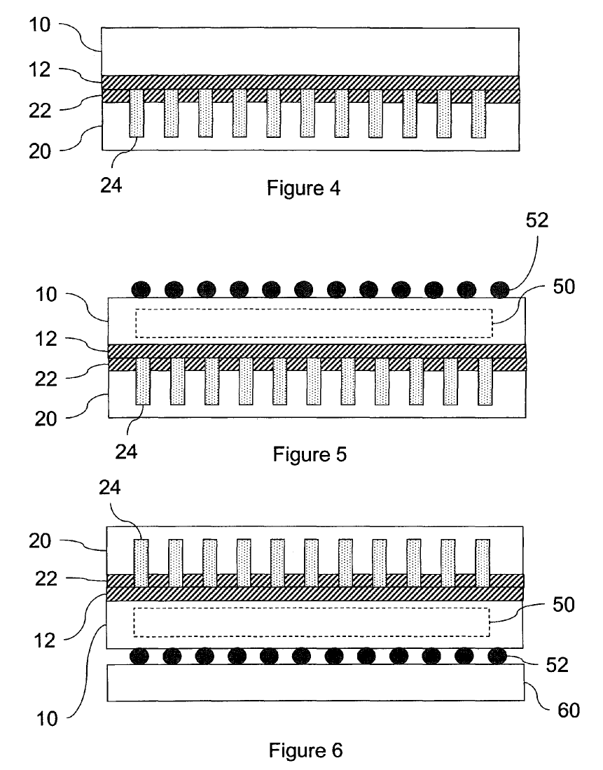

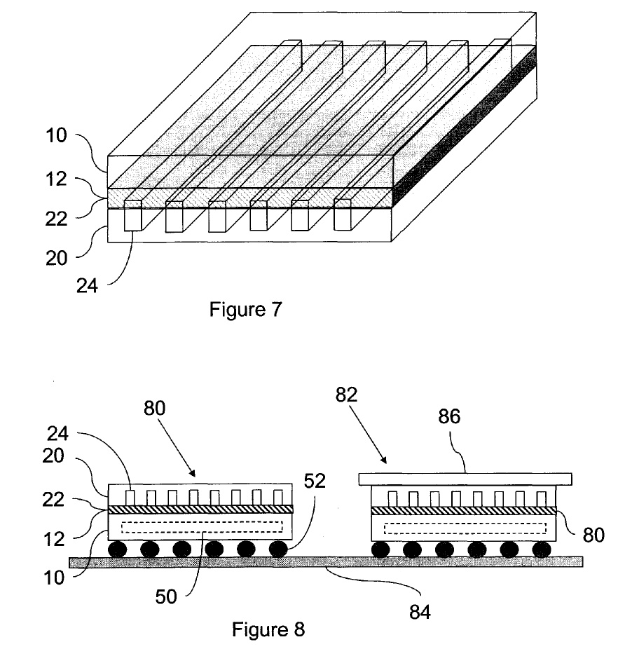

As shown in FIG. 3, the first wafer 10 is inverted and bonded to the second wafer 20. This bonding process can comprise any conventional attachment process including the use of an adhesive between the substrates, heating the substrates, etc. There are several bonding techniques that exist. The most common include fusion, eutectic, anodic and intermediary-layer techniques. In fusion bonding, two similar materials are held together and heated until the surfaces flow into each other. Eutectic bonding is similar but uses wafers with two different surface materials, so that upon heating an alloy forms at the interface. In anodic bonding, two surfaces are brought together and a high voltage is applied across the interface. The voltage causes migration of ions across the interface, resulting in opposing space charges. Electrostatic force then holds the surfaces together. Some wafer-bonding processes use an intermediate layer between wafers to act as an adhesive. Such bonding processes are well-known to those ordinarily skilled in the art and are not discussed in detail herein. The bonding process should not interfere with the thermal path between the thermal conductors 24 and the substrate 10. Therefore, if an adhesive is utilized in the bonding process, the adhesive should be highly thermally conductive and not insulative. The bonded structure is shown in cross-sectional view FIG. 4, and in perspective view in FIG. 7. The second wafer 20 has a coefficient of thermal expansion that matches a coefficient of thermal expansion of the first wafer 10.

One feature of the invention is that the thermal conductors extend to the very edge of the second wafer 20 that will contact the first wafer 10 (and/or the cap dielectric 12 that is formed on the first wafer 10). This allows the thermal conductors 24 to be as close to the first wafer 10 as possible and preferably to actually physically contact and connect to the first wafer 10.

In FIG. 5, conventional integrated circuit structures 50, such as wiring, transistors, storage devices, etc. and chip carrier connections 52 are formed on the side of the first wafer 10 that is opposite to where the first wafer 10 is bonded to the second wafer 20, and then the first wafer 10 is bonded to a chip carrier 60 as shown in FIG. 6. The micro-channels 24 that are embedded inside each chip can have many different configurations. One simple example, as shown in FIG. 7, is parallel through chip channels. When selecting the orientation of the channels, one may need to consider package parameters, such as the fan location, air flow pattern, etc.

Therefore, rather than including internal cooling structures within the portion of the substrate that houses the active circuitry, the invention separately forms a portion of the wafer that is dedicated exclusively to cooling devices and then bonds this cooling portion to the other active circuitry portion of the wafer prior to forming the actual circuits. This process does not increase the thickness of the overall substrate, even though multiple wafer sections are bonded together, because the thickness of each of the substrates is approximately one-half of the minimum required substrate thickness for the given structure. More specifically, neither the first wafer 10, nor the second wafer 20, alone would be thick enough to provide necessary structural support during manufacturing for a given design. Instead, only the combined thicknesses of the first wafer 10 and the second wafer 20 would provide sufficient structural support during the process of forming the active circuitry 50, dicing the wafers into chips, and attaching the chipset to chip carriers 60. Therefore, the invention achieves the physical separation of the cooling portion of the wafer substrate from the active circuitry portion of the wafer substrate, without increasing the overall thickness of the substrate that would be required for given design. Thus, the invention forms a plurality of cross-chip micro-channels inside the silicon substrate during substrate preparation. These micro-channels significantly improve the surface contact areas which allow efficient thermal dissipation from the back side of the wafer.

Thus, the invention produces laminated integrated chip structures 80, 82 that have a thermally conductive wafer 20 connected to the portion of the chip 10 that contains the actual circuits, as shown in FIG. 8. In another embodiment, shown in FIGS. 8-10, the invention can connect multiple laminated chip structures 80, 82 to a flexible substrate 84 and fold the flexible substrate 84 to stack the laminate chip structures 80, 82 on top of each other. Note that the internal structures illustrated in FIGS. 1-4 are not numbered in all instances in FIGS. 8-10 in order to make the drawings more clear; however, the chips structures 80, 82 include all the features shown in FIGS. 1-4. More specifically, the invention connects a first laminated chip structure 80 and a second laminated chip structure 82 to the flexible substrate 84. For example, the first and second laminated chip structures 80 can each comprise a first portion 10 comprising circuits 50 and a second portion 20 comprising trenches filled with thermal conductors 24.

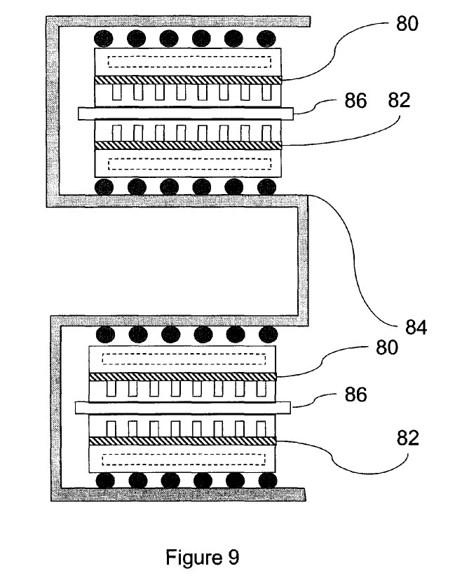

A thermally conductive surface (e.g., a thermal plate) 82 is joined to the top (second portion 20) of a first of the laminated chip structures 82. This embodiment then folds the flexible substrate 84 such that the top (second portion 20) of the second laminated chip structure 80 contacts the thermal plate 86 as shown in FIG. 9. This process of folding the flexible substrate 84 inverts the second integrated circuit chip structure 80 with respect to the first integrated circuit chip structure 82 and positions the thermal plate 86 between the tops of the two chips. The first integrated circuit chip 82 and the second integrated circuit chip 80 are positioned such that the thermal conductors 24 are between the thermally conductive surface 86 and the circuits 50. Then, the second integrated circuit chip 80 is bonded to the thermal plate 86.

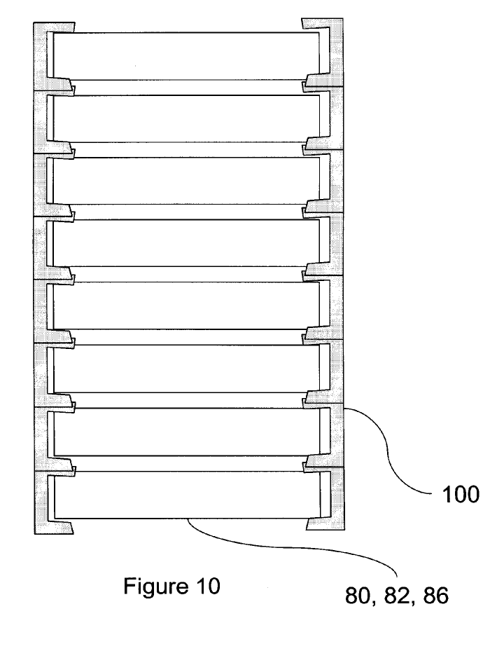

As also shown in FIG. 9, multiple sets of attached chips 80, 82, 86 can be connected to the flexible chip carrier 84 such that a stacked structure having multiple sets of attached chips 80, 82, 86 can be created. While two sets of attached chips 80, 82, 86 are shown in FIG. 9, one ordinarily skilled in the art would understand that many more sets of attached chips 80, 82, 86 could be stacked upon each other, depending upon the specific design, as shown in FIG. 10. In FIG. 10, the flexible substrate 100 is utilized on both sides of the sets of attached chips 80, 82, 86 to provide the necessary structural support. Thus, the invention uses two flip-chips having embedded micro-channels that can be packed back-to-back in a FLEX-type package structure to save package area. Similarly, multiple chips having embedded micro-channels can be stacked in a surface-mount package structure to save package area.

One advantage of the on-chip micro-channels that are discussed above is that they can be packed in the back-to-back stacked structure shown in FIGS. 9 and 10. The flexible polyimide substrate such as a FLEX type package is becoming very popular in today's high-density package environment. It is commonly found in the portable consumer electronics, such as cell phone, PDA, etc., due to its flexibility and small size. Compared to a conventional chip without embedded micro-channels, the invention allows two chips to be stacked back-to-back and thus save package space. This method is desirable for chips stacking package where at least two chips are stacked in the vertical direction. Micro-channels 24 on each chip allow cooling capacity to which no other conventional method can be compared. This has wide range of applications, including stacking different memory modules together.

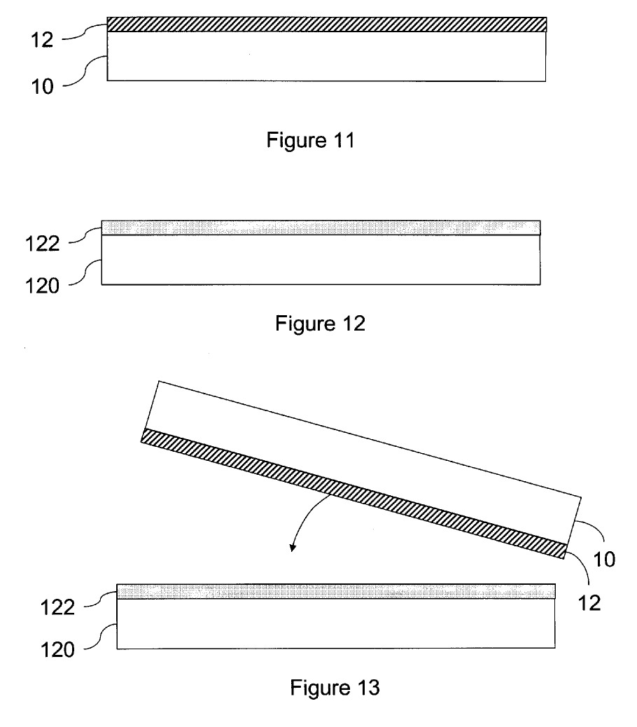

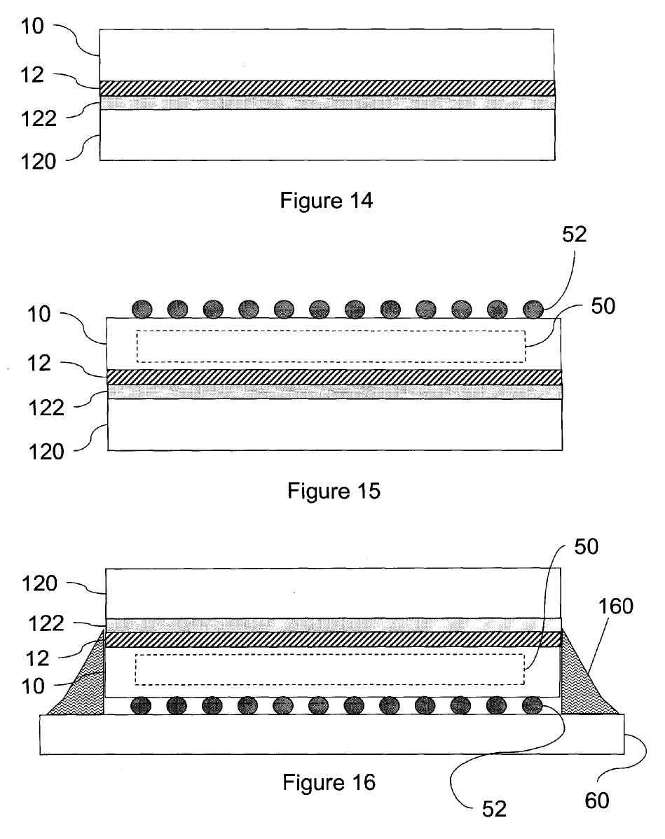

In another embodiment, shown in FIGS. 11-18, the invention uses a sacrificial second wafer during the circuitry formation and replaces the sacrificial wafer with an external heat sink. During this processing, the sacrificial wafer supplies the necessary structural support; however, because it is removed and replaced with a similarly sized external heat sink, the overall thickness of the structure is reduced. Thus, the invention prepares a wafer substrate which is formed by bonding two thinner wafers together. After the IC is fabricated, and C4 (Control Collapse Chip Connection) or conventional bumps are formed, the chip is flip-bonded to a chip carrier. The thin layer on the back side of the wafer used for mechanical support during processing can then be removed. The objective is to reduce wafer thickness, and replace it with a high-thermal conductive material to improve the thermal conductivity.

In this embodiment, the invention bonds a first wafer 10 to a sacrificial wafer 120 as shown in FIGS. 11-14. This processing a substantially similar to that discussed above with respect to FIGS. 1-4 and the same features are identified with the same numbers and a redundant discussion of the same is avoided. The sacrificial wafer 120 is similar to the wafers 10, 20 that are discussed above except that instead of a cap dielectric 22, a bonding material 122 having specific characteristics is utilized. More specifically, this bonding material 122 produces a non-permanent bond that can be disconnected in subsequent processing. For example, the bonding material 122 can comprise a low temperature adhesive, an organic polymer, thermal paste, or other similar materials that can be dissolved and/or melted to allow the sacrificial wafer 120 to be selectively removed from the wafer 10 when desired.

As discussed above, as shown in FIG. 15, internal active circuitry 50 and chip carrier connections 52 are also formed in the structure. Next, as shown in FIG. 16, the integrated circuit chip is connected to the chip carrier 60. In this embodiment, additional structural support is provided through bonding agents 160 that are formed using conventional, well-known processes.

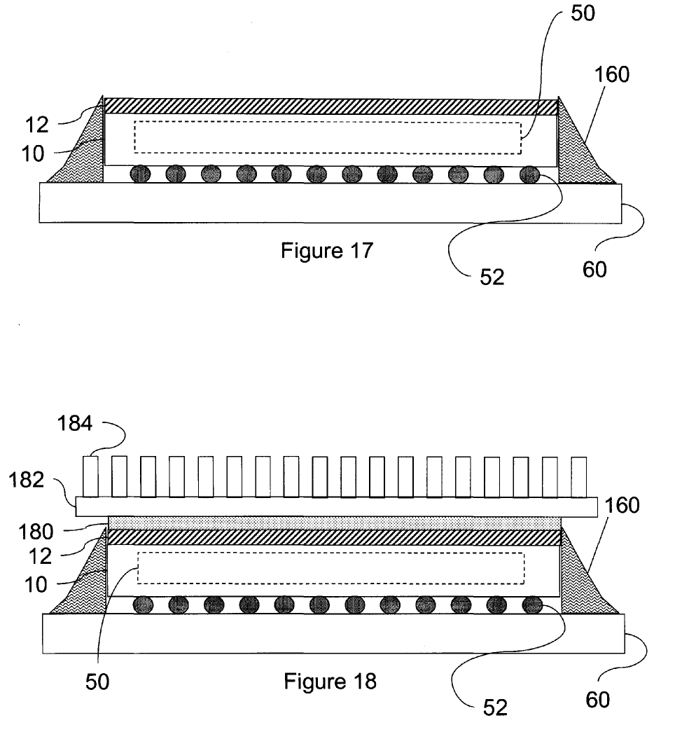

Next, as shown in FIG. 17, this embodiment removes the sacrificial wafer 120 using any well known material removal process such as ultra-high density plasma, or lift-off and stop at the inter-dielectric layer. This removal process will vary depending upon the bonding material 122 utilized. If the bonding material 122 is a low temperature adhesive, localized or general heating can be utilized to soften the bonding material 122, after which the wafer 120 can be physically removed or rinsed from the structure. Similarly, if the bonding material 122 comprises an organic polymer, the structure can be rinsed with an appropriate chemical agent to dissolve the organic polymer, thereby causing the sacrificial wafer 120 to be disconnected from the wafer 10. This is different than trying to reduce wafer thickness through the use of a mechanical grinding process. With mechanical grinding, damage to the devices and the circuits are the major concern. Using, wet or dry etching process is slow and thus expensive. In addition, there is no reliable etching stop mechanism and it is difficult to control the final die thickness using etching.

Then, as shown in FIG. 18, an optional heat sink 182 having air-cooled cooling fins 184 or any other highly thermally conductive structure or material (such as these discussed above) can be attached to the integrated circuit chip using a bonding agent 180 or other similar thermally conductive material that will provide sufficient adhesive strength to hold the heat sink 182 on the integrated circuit chip. The manufacturing processes and materials used to create such heat sinks 22 are well-known to those ordinarily skilled in the art and a detailed discussion thereof is not included herein.

As discussed above, this embodiment of the invention produces a structure with an external heat sink without substantially increasing the thickness of the integrated circuit chip and heat sink combination. Thus, the inventive chip/heat sink combination has about the same thickness as a conventional chip alone. Wafer thickness is proportional to wafer size. In 300 mm diameter wafer, the thickness is about 0.7-0.9 mm. A minimum thickness is necessary to guarantee that the wafer has sufficient mechanical strength necessary to sustain stress during manufacturing, testing, and bumping processes. The concept here is that, when all the high-stress processes are done, the thickness of the chip can be significantly reduced.

More specifically, as discussed above, the wafer portion 10 is approximately half the thickness necessary to provide mechanical and structural support during the formation of the internal circuitry 50, carrier attachment, etc. Because of the use of the attached sacrificial wafer 120 during such processing, even when this thickness of the wafer 10 is combined with the thickness of the heat sink 184, the overall thickness is approximately the same as the minimum wafer thickness that would be required to provide such necessary structural and mechanical support during the manufacturing process. Therefore, the invention provides a structure that includes an optional external heat sink that has approximately the same thickness of a similar conventional integrated circuit chip that does not include the external heat sink. The structure shown in FIG. 18 can also be connected to a flexible chip carrier as shown in FIGS. 8-10, above.

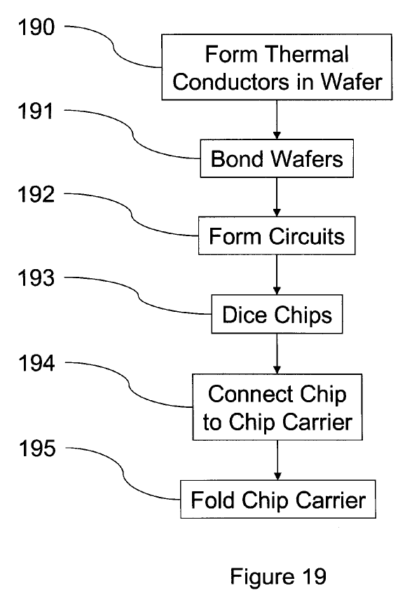

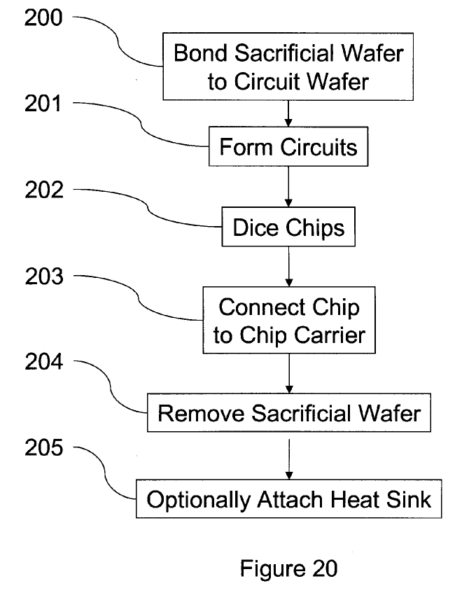

FIGS. 19 and 20 illustrate some of the differences between the two main embodiments described herein. More specifically, in FIG. 19, the first embodiment begins in item 190 by forming the thermal conductors in the cooling wafer as a pre-fabrication step. Next, the wafers are bonded together in item 191. Subsequently, circuits are formed in the circuit wafer (not the cooling wafer) in item 192. In item 193, the wafers are diced into chips and, in item 194, the chips are connected to either a conventional chip carrier or a flexible chip carrier. If the chips are connected to the flexible chip carrier, in item 195, the flexible chip carrier can be folded upon itself to form pairs of attached chips to be stacked, as discussed above.

In the second main embodiment, as shown in FIG. 20, the process begins by bonding the sacrificial wafer to the circuit wafer in item 200. Then, circuits are formed in item 201 and the wafers are diced into chips in item 202. Next, the chip is connected to a chip carrier in item 203. After this, the sacrificial wafer is removed, in item 204, and is replaced with the optional heat sink or other heat dissipating structure in item 205.

Thus, the invention presents micro-channel structures that are prefabricated during wafer substrate preparation. After the chip is processed, tested, and contact bumps are formed, the wafer is diced. After dicing, a plurality of cooling channels are revealed on at least two sides of the chip. A sandwiched chip structure is also formed by the wafer bonding technique that allows the backside of the silicon wafer to be removed easily. After dicing, the chip is flipped and bonded on a substrate. The backside silicon layer can be removed by ultra-high density plasma, or lift-off and stop at the inter-dielectric layer. Since mechanical grinding is not necessary, potential damages on the finished chip can be eliminated.

One advantage the invention provides is compact size packaging. The invention also provides high yield because it avoids any combination of die thinning process. The invention also provides efficient cooling and can incorporate both active and passive cooling devices.

While the invention has been described in terms of preferred embodiments, those skilled in the art will recognize that the invention can be practiced with modification within the spirit and scope of the appended claims.

What is claimed is:

1. An integrated circuit chip comprising:
a first wafer; and
a second wafer bonded to said first wafer,
wherein said first wafer comprises circuits, and
wherein said second wafer is more thermally conductive than said first wafer.

2. The integrated circuit chip in claim 1, further comprising thermal conductors within said second wafer.

3. The integrated circuit chip in claim 2, wherein said thermal conductors have a higher coefficient of thermal conductivity than said second wafer.

4. The integrated circuit chip in claim 2, wherein said thermal conductors are sealed within said second wafer.

5. The integrated circuit chip in claim 2, wherein said thermal conductors comprise one of a plurality of thermoelectric devices and trenches containing material having a higher coefficient of thermal conductivity than said second wafer.

6. The integrated circuit chip in claim 1, wherein said first wafer further comprises chip carrier connections on a first side of said first wafer that is opposite to where said first wafer is bonded to said second wafer.

7. The integrated circuit chip in claim 1, wherein said second wafer has a coefficient of thermal expansion that matches a coefficient of thermal expansion of said first wafer.

8. An integrated circuit chip comprising:
a first wafer; and
a second wafer bonded to said first wafer,
wherein said first wafer comprises circuits, and
wherein said second wafer comprises trenches filled with thermal conductors.

9. The integrated circuit chip in claim 8, wherein said first wafer further comprises chip carrier connections on a first side of said first wafer that is opposite to where said first wafer is bonded to said second wafer is bonded to said first wafer.

10. The integrated circuit chip in claim 8, wherein said thermal conductors are sealed within said second wafer.

11. The integrated circuit chip in claim 10, wherein said thermal conductors are sealed within said second wafer by bonding material between said first wafer and said second wafer.

12. The integrated circuit chip in claim 8, wherein said second wafer has a coefficient of thermal expansion that matches a coefficient of thermal expansion of said first wafer.

13. The integrated circuit chip in claim 8, wherein said thermal conductors comprise a plurality of thermoelectric devices.

14. The integrated circuit chip in claim 8, further comprising a thermally conductive surface connected to a first side of said second integrated circuit chip that is opposite to a second side of said second wafer where said second wafer is bonded to said first wafer.

15. An integrated circuit chip structure comprising:
a first integrated circuit chip;
a thermally conductive surface having a first side and a second side opposite said first side, wherein said first side of said thermally conductive surface is joined to said first integrated circuit chip; and
a second integrated circuit chip connected to said second side of said thermally conductive surface,
wherein said first integrated circuit chip and said second integrated circuit chip each comprise a first portion comprising circuits and a second portion comprising trenches filled with thermal conductors, and
wherein said first integrated circuit chip and said second integrated circuit chip are positioned such that said thermal conductors are between said thermally conductive surface and said circuits.

16. The integrated circuit chip in claim 15, further comprising a flexible substrate connected to first sides of said first integrated circuit chip and said second integrated circuit chip, wherein said first sides of said first integrated circuit chip and said second integrated circuit chip are opposite second sides of said first integrated circuit chip and said second integrated circuit chip that are connected to said thermally conductive surface.

17. The integrated circuit chip in claim 16, wherein said first integrated circuit chip, said second integrated circuit chip and said thermally conductive surface comprise a laminated structure and said flexible substrate wraps around said laminated structure.

18. The integrated circuit chip in claim 15, wherein said first integrated circuit chip and said second integrated circuit chip each comprise chip carrier connections on first sides of said first integrated circuit chip and said second integrated circuit chip, wherein said first sides of said first integrated circuit chip and said second integrated circuit chip are opposite second sides of said first integrated circuit chip and said second integrated circuit chip that are connected to said thermally conductive surface.

19. The integrated circuit chip in claim 15, wherein said thermal conductors are sealed within said first integrated circuit chip and said second integrated circuit chip.

20. The integrated circuit chip in claim 15, wherein said thermal conductors comprises a plurality of thermoelectric devices.

21. The integrated circuit chip in claim 15, wherein said first integrated circuit chip is inverted with respect to said second integrated circuit chip.

22. A method of forming an integrated circuit chip, said method comprising:
providing in a first wafer;
forming thermal conductors in a second wafer;
bonding said second wafer to said first wafer; and
forming circuits in said first water.

23. The method in claim 22, wherein said thermal conductors have a higher coefficient of thermal conductivity than said second wafer.

24. The method in claim 22, wherein said bonding process seals said thermal conductors within said second wafer.

25. The method in claim 22, wherein said process of forming said thermal conductors comprises forming thermoelectric devices within said second wafer.

26. The method in claim 22, wherein said process of forming said thermal conductors comprises:
forming trenches in said wafer; and
filling said trenches with material having a higher coefficient of thermal conductivity than said second wafer.

27. The method in claim 22, further comprising forming chip carrier connections on a first side of said first wafer that is opposite to where said first wafer is bonded to said second wafer.

28. The method in claim 22, wherein said second wafer has a coefficient of thermal expansion that matches a coefficient of thermal expansion of said first wafer.

29. A method of forming an integrated circuit chip, said method comprising:
bonding a thermally conductive surface to a first laminated chip structure, wherein said thermally conductive surface has a first side and a second side opposite said first side, and wherein said first side of said thermally conductive surface is joined to said first laminated chip structure;
connecting said first laminated chip structure and a second laminated chip structure to a flexible substrate, wherein said first laminated chip structure and said second laminated chip structure each comprise a first portion comprising circuits and a second portion comprising trenches filled with thermal conductors;
folding said flexible substrate such that said second laminated chip structure contacts said second side of said thermally conductive surface, and said first laminated chip structure and said second laminated chip structure are positioned such that said thermal conductors are between said thermally conductive surface and said circuits; and
bonding said second side of thermally conductive surface to said second laminated chip structure.

30. The method in claim 29, wherein said thermal conductors have a higher coefficient of thermal conductivity than wafer portions of said first laminated chip structure and said second integrated circuit.

31. The method in claim 29, wherein said thermal conductors are sealed within said second wafer.

32. The method in claim 29, wherein said process of folding said flexible substrate inverts said second laminated chip structure with respect to said first laminated chip structure.

33. The method in claim 29, wherein said thermal conductors comprise one of a plurality of thermoelectric devices and trenches containing material having a higher coefficient of thermal conductivity than said second wafer.

34. The method in claim 29, further wherein said process of connecting said first laminated chip structure and said second laminated chip structure to said flexible substrate comprises forming chip carrier connections on said first laminated chip structure and said second laminated chip structure.

35. The method in claim 29, further comprising repeating said method to form a stack of pairs of laminated chip structures.

36. A method of forming an integrated circuit structure comprising:
bonding a first wafer to a sacrificial wafer;
forming circuits in said first wafer;
attaching said first wafer to a chip carrier; and
disconnecting said sacrificial wafer from said first wafer.

37. The method in claim 36, wherein said process of bonding said first wafer to said sacrificial wafer forms a non-permanent bond that is broken during said process of disconnecting said sacrificial wafer from said first wafer.

38. The method in claim 36, further comprising dicing said wafer into integrated circuit chips after forming said circuits and before attaching said first wafer to said chip carrier.

39. The method in claim 36, further comprising bonding a heat sink to said first wafer, wherein said heat sink comprises an air-cooled structure with cooling fins.
